(19) United States
(12) Patent Application Publication
(10) Pub. No.: US 2025/0015582 A1
(43) Pub. Date: Jan. 9, 2025

(54) Device For Connecting An Electrical Component To A Component To Be Electrically Insulated Therefrom

(71) Applicant: Eugen Forschner GmbH, Spaichingen (DE)

(72) Inventors: Martin Dopadlo, Spaichingen (DE); Xu Zhang, Spaichingen (DE); Henning Sdun, Spaichingen (DE); Matthias Goldsche, Spaichingen (DE)

(73) Assignee: Eugen Forschner GmbH, Spaichingen (DE)

(21) Appl. No.: 18/713,376

(22) PCT Filed: Nov. 28, 2022
(86) PCT No.: PCT/EP2022/083389

§ 371 Date: May 24, 2024

(30) Foreign Application Priority Data
Nov. 29, 2021 (DE) 102021131306.6
Dec. 17, 2021 (DE) 1021133689.9

(51) Int. Cl. H02G 5/10; H05K 7/14; H05K 7/20

(52) U.S. Cl. CPC H02G 5/10; H05K 7/1407; H05K 7/2039

(57) ABSTRACT

An apparatus for connecting an electrical component to a component to be electrically insulated therefrom includes an electrically insulating support for transmitting mechanical loads between the electrical component and the component to be electrically insulated therefrom, an electrically insulating heat transfer unit for transmitting thermal loads between the electrical component and the component to be electrically insulated therefrom, and an attachment unit, which can be directly connected to the electrical component, for attaching the support to the electrical component. The heat transfer unit is detachably connected to the support.

### TECHNICAL FIELD

The present invention relates to an apparatus for connecting an electrical component to an insulated component to be electrically insulated therefrom. The electrical component is, for example, a busbar and/or a printed circuit board. The insulated component to be electrically insulated from the electrical component is, for example, a housing. The apparatus has an electrically insulating support, an electrically insulating heat transfer unit and an attachment unit.

The invention also relates to a connection assembly in which a busbar and a housing are connected to each other by an apparatus of the above-mentioned type.

### BACKGROUND

An apparatus for connecting an electrical component to a housing is known from EP 2 871 921 B1. The apparatus comprises an electrically insulating body, a housing body and a busbar. The housing body and the electrically insulating body are connected in one piece. The busbar is embedded in the electrically insulating body. In the apparatus known from the prior art, both mechanical loads, such as forces and/or torques, and thermal loads, such as the waste heat from the electrical component, are transmitted equally via the housing body and the electrically insulating body. This can lead to reduced durability of the apparatus. In addition, the entire apparatus must be newly manufactured for each desired thermal conductivity.

Based on the above prior art, it is an object of the present invention to provide an apparatus which eliminates the above problems and disadvantages of the prior art. In particular, it is an object of the present invention to provide an apparatus for connecting an electrical component to an insulated component to be electrically insulated therefrom, which is easy to manufacture, durable and more versatile in terms of thermal conductivity.

### SUMMARY

The object is solved by an apparatus according to claim 1 and a connection assembly according to claim 10. Advantageous further embodiments of the invention are the subject of the dependent claims.

The solution according to the invention consists in particular in providing an apparatus for connecting an electrical component to an insulated component to be electrically insulated from the electrical component, preferably in an electric vehicle. The electrical component can be, for example, a busbar, a conductor track and/or a printed circuit board. In particular, the electrical component is a high-voltage component. The insulated component to be electrically insulated therefrom can be, for example, a housing or a housing wall. In particular, the housing can be a housing for high-voltage components, for example a high-voltage junction box. Preferably, the high-voltage junction box is for an electric vehicle and is used in an electric vehicle.

The apparatus according to the invention comprises an electrically insulating support, an electrically insulating heat transfer unit and an attachment unit. The support is configured to transmit mechanical loads between the electrical component and the insulated component to be electrically insulated therefrom. The heat transfer unit is configured to transfer thermal loads between the electrical component and the insulated component to be electrically insulated therefrom. The attachment unit can be directly connected to the electrical component and is suitable for attaching the support to the electrical component. According to the invention, the heat transfer unit is detachably connected to the support.

In the following, the term “mechanical loads” is understood to mean forces and/or moments that can act between the electrical component and the insulated component to be electrically insulated therefrom. For example, the insulated component may be exposed to acceleration forces that must be transferred to the electrical component.

In the following, the term “thermal load” refers to the exchange of thermal energy, in particular the exchange of heat, between a first component and a second component. The term “heat” can therefore be used instead of the term “thermal load”. The first component can be connected to the second component in a heat-communicating manner via a third component. For example, the electrical component can generate waste heat, which is dissipated to the housing by means of the apparatus.

One advantage of the apparatus according to the invention is that the heat transfer unit can be easily replaced if the thermal conductivity of the apparatus needs to be adjusted. For this purpose, the heat transfer unit can, for example, be detached from the support and replaced with another heat transfer unit that has a different thermal conductivity. A further advantage of the apparatus according to the invention is that a first component, namely the support, is primarily used to transmit the mechanical loads and a second component, namely the heat transfer unit, is primarily used to transmit the thermal loads. This means that the transmission of mechanical loads is decoupled from the transmission of thermal loads. This leads to improved durability of the apparatus.

In a first exemplary embodiment of the apparatus, the attachment unit is configured to transmit mechanical loads between the electrical component and the support. In addition, the attachment unit can be configured to transfer thermal loads between the electrical component and the heat transfer unit. For example, the attachment unit can be connected to the support in a form-fitting, force-fitting and/or material-fitting manner. Preferably, the attachment unit is immovably connected to the support. In addition, the attachment unit can be connected to the heat transfer unit in a heat-communicating, i.e. heat-conducting, manner.

For example, the attachment unit can have a coupling element. The attachment unit can be connected to the electrical component via the coupling element, in particular be immovably connected. The coupling element can be designed in such a way that the attachment unit is connected to the electrical component in a form-fitting, force-fitting and/or material-fitting manner. For example, the coupling element can be configured as a connection surface that can be glued or welded to the electrical component. Alternatively, the attachment unit can also be configured in one piece with the electrical component. Alternatively, the attachment unit can also have a recess with a threaded or latching device with which a fastening part, such as a screw, can be engaged. The electrical component is then preferably sandwiched between the fastening part and the attachment unit.

Independently of the coupling element, the attachment unit can have a connecting element. The attachment unit can be connected to the support via the connecting element, in particular it can be detachably connected to the support. The connecting element can be designed in such a way that the attachment unit is connected to the support in a form-fitting, force-fitting and/or material-fitting manner. Preferably, the attachment unit is immovably connected to the support via the connecting element. For example, the connecting element is a latching device that latches with the support. Furthermore, for example, the connecting element is a screw thread that engages in a corresponding screw thread on the support when connected. The attachment unit can then be form-fitting and detachably connected to the carrier. This has the advantage that the attachment unit is easy to manufacture and can be easily connected to the support.

The attachment unit can have a heat transfer element independently of the coupling element and independently of the connecting element. Preferably, the heat conducting element is configured in such a way that heat can be transferred from the attachment unit to the heat transfer unit by mechanical contact between the attachment unit and the heat transfer unit. For example, the heat transfer element of the attachment unit can be a surface that is in contact with the heat transfer unit. Preferably, the attachment unit is made of a thermally conductive material.

Particularly preferably, the attachment unit, particularly including the coupling element, the connecting element and the heat transfer element, is configured in one piece. Thus, the coupling element can also be understood as the coupling surface or area, the connecting element can also be understood as the connecting surface or area and the heat transfer element can also be understood as the heat surface or area of the attachment unit.

In another exemplary embodiment, the support can be connected to the insulated component in a form-fitting and/or force-fitting manner.

Preferably, the support spans the heat transfer unit. The support is thus configured such that it partially extends laterally beyond the heat transfer unit. In general, the support preferably has fastening regions for fastening the support to the insulated component.

These fastening regions can be configured on the lateral regions that extend beyond the heat transfer unit. The support can be fastened to the insulated component at the fastening regions. Fastening at the fastening regions can be carried out, for example, by means of fastening elements such as screws and the like.

The support can, for example, have at least two fastening regions, each of which protrude at least partially beyond the heat transfer unit on one side of the heat transfer unit. In particular, the two fastening regions are arranged on two opposite sides of the heat transfer unit.

For example, the support, in particular at the fastening regions, can have holes, in particular long holes, via which the support can be screwed to the insulated component or component to be insulated. This has the advantage that the apparatus for connecting the electrical component to the insulated component can be easily mounted. Advantageously, the support is made of an electrically insulating material.

Spacer rings can also be arranged on the holes to secure the support. Preferably, the spacer rings are configured from steel. Furthermore, the spacer rings are preferably inserted into the support, in particular pressed in. Alternatively, they are used as insert rings. In general, the spacer rings make it possible to attach the support particularly securely to the insulated component to be electrically insulated. The spacer rings can prevent deformation, for example creep, of the support.

Due to the design of the support spanning the heat transfer unit, the heat transfer unit can be clamped between the support and the insulated component. The heat transfer unit therefore does not have to be attached directly to the insulated component, but can be attached indirectly by means of the electrically insulating support. The heat transfer unit therefore does not, for example, have its own fastening devices or fastening regions, such as drilled holes, for fastening to the insulated component.

In other words, the heat transfer unit is attached to the insulated component, preferably exclusively, by means of the fastening regions of the support.

Irrespective of this, the electrically insulating support is preferably configured in one piece from an electrically insulating material. Preferably, the support is configured in such a way that it accommodates or at least partially encloses the heat transfer unit.

In an exemplary further development of the apparatus according to the invention, the heat transfer unit is detachably and/or immovably connected to the support. In particular, the heat transfer unit is connected to the support in a form-fitting manner. This has the advantage that the heat transfer unit can be replaced quickly and easily if a different thermal conductivity is required. For example, the heat transfer unit can be connected to the support via a snap-fit connector. Preferably, the support comprises at least one mating part for this purpose, which engages in at least one snap-in groove of the heat transfer unit when the support is connected to the heat transfer unit. The mating part can be configured in such a way that it deforms elastically during the connection and engages in the snap-in groove when the support and the heat transfer unit are positioned in the desired position relative to each other. To release the connection between the support and the heat transfer unit, the mating part can preferably be released from engagement with the snap-in groove by elastic deformation. Particularly preferably, the support has a recess into which the heat transfer unit can be inserted in a form-fitting manner. The recess is thus configured to complement an outer contour of the heat transfer unit.

Particularly preferably, the heat transfer unit and/or the support has an anti-rotation device. The anti-rotation device is configured to prevent the heat transfer unit and the support from rotating relative to each other. For example, the anti-rotation device can have at least one protrusion on the heat transfer unit or on the support and a complementary shaped recess on the other element, i.e. the support or the heat transfer unit.

If the support has a recess into which the heat transfer element can be inserted in a form-fitting manner, this recess can also form the anti-rotation device.

The electrically insulating support can be configured to be thermally insulating. This means that the support preferably transfers almost no thermal energy between the electrical component and the insulated component to be electrically insulated from the electrical component. This has the advantage that the overall thermal conductivity of the apparatus depends almost exclusively on the thermal conductivity of the heat transfer unit. If the overall thermal conductivity of the apparatus is to be predetermined, the heat transfer unit can be adapted accordingly without having to take the thermal conductivity of the support into account. Alternatively, the support has a significantly lower thermal conductivity than the heat transfer unit. This means that the thermal conductivity of the support is 70% lower in relation to the thermal conductivity of the heat transfer unit, preferably 80% lower and particularly preferably 90% lower. Advantageously, this causes the heat exchange between the electrical component and the insulated component to take place essentially via the heat transfer unit. This has the advantage that the transmission of the mechanical loads is decoupled from the transmission of the thermal loads. Preferably, the heat transfer unit is not configured to transmit mechanical loads.

By decoupling the mechanical loads and thermal loads, a separation of the functions is achieved. As a result, only the mechanical loads and not the thermal loads need to be taken into account when designing the support. Similarly, only the thermal loads and not the mechanical loads need to be taken into account when designing the heat transfer unit. This means that other materials can be used. This means, for example, that the choice of material for the heat transfer unit is more flexible, i.e. not so restricted. In particular, materials with very good thermal conductivity can be used for the heat transfer unit, which would actually be too brittle for transmitting mechanical loads. A heat transfer unit made from this material could not, for example, be attached directly to the insulated component using screws.

In an exemplary further development, both the support and the heat transfer unit are made of an electrically insulating plastic. This has the advantage that the support and the heat transfer unit can be manufactured easily. For example, the support and/or the heat transfer unit can be manufactured by injection molding or an additive manufacturing process. Irrespective of this, the support can be configured as a lightweight component. For example, the support comprises weight-reducing structures.

The electrically insulating heat transfer unit is preferably made of a material with very good thermal conductivity, in particular a plastic with very good thermal conductivity. Preferably, the heat transfer unit has a thermal conductivity of more than 1.5 W/(m·K). The heat transfer unit can be configured as a plastic block or plastic cylinder. The material of the heat transfer unit can be thermoplastics, thermosets or elastomers. In particular, the material can be polypropylene (PP), polyphthalamide (PPA), polyamide (in particular PA 6, PA 66 or PA 12), thermoplastic copolyesters (COPE), polyphenylene sulphide (PPS), liquid crystal polymer (LCP), thermoplastic elastomers (TPE), polycarbonates/acrylonitrile butadiene styrene (PC/ABS blend), polyether ether ketone (PEEK), polyetherimide (PEI) or polybutylene terephthalate (PBT). A ceramic and/or mineral filler can be added to these plastics to improve their thermal conductivity. Aluminum oxide or boron nitride are particularly suitable for this purpose.

In an exemplary further development, the heat transfer unit can be manufactured using an extrusion process. For example, the heat transfer unit is a solid profile that is extruded and then cut to the required dimensions.

The heat transfer unit can have fillers that increase the thermal conductivity of the heat transfer unit. Preferably, the fillers are arranged within the heat transfer unit. The arrangement of the fillers within the heat transfer unit can be in the form of strips or rods. The orientation of the fillers corresponds in particular to the desired heat transfer direction. In other words, the fillers are configured according to the expected temperature gradient in the heat transfer unit. Advantageously, the fillers are introduced into the heat transfer unit during the extrusion process.

In another exemplary embodiment, the heat transfer unit has a first heat transfer surface and a second heat transfer surface. The first heat transfer surface can be connected to the electrical component in a heat-communicating manner. For example, the first heat transfer surface can be in direct mechanical contact with the attachment unit, in particular with the heat transfer element of the attachment unit.

The second heat transfer surface is preferably arranged opposite the first heat transfer surface. The second heat transfer surface can be connected in a heat-communicating manner to the insulated component to be electrically insulated from the electrical component. For example, the second heat transfer surface can be in direct mechanical contact with the insulated component. In addition, a thermally conductive sheet can be provided between the second heat transfer surface and the insulated component.

Advantageously, the heat transfer unit absorbs heat via the first heat transfer surface. In particular, heat can be absorbed from the electrical component via the first heat transfer surface. The heat transfer unit can dissipate heat via the second heat transfer surface, in particular dissipate heat to the insulated component.

In an exemplary further development of the above embodiment, the first heat transfer surface is smaller than the second heat transfer surface. This has the advantage of ensuring that the heat that is absorbed by the heat transfer unit via the first heat transfer surface can in any case be dissipated via the second heat transfer surface. Irrespective of this, in embodiments in which the heat transfer unit has fillers, the fillers can extend from the first heat transfer surface in the form of strips or rods to the second heat transfer surface.

The initial object is also solved by a connection assembly comprising a busbar, a housing and an apparatus according to the above embodiments. According to the invention, the apparatus detachably connects the busbar to the housing. Preferably, the busbar forms the electrical component in the connection assembly. The housing can be the insulated component to be electrically insulated from the busbar.

Particularly advantageously, the apparatus according to the invention can be used to arrange an electrical component, in particular a high-voltage component, inside a housing, in particular a high-voltage distributor housing. For example, an electrical component configured as a high-voltage fuse and/or a busbar connected to the high-voltage fuse can be arranged on the high-voltage distributor housing wall in such a way that the apparatus according to the invention can be used not only for mechanical attachment to the high-voltage distributor housing wall, but also for heat dissipation to the high-voltage distributor housing wall, in particular targeted heat dissipation of heat generated in the high-voltage fuse. With its large surface area, the high-voltage distributor housing wall serves as a suitable heat sink from which the heat can be further dissipated.

In the use described above, the apparatus according to the invention is well suited to dissipating the power loss generated in the charging path of the high-voltage fuse as heat.

### BRIEF DESCRIPTION OF THE DRAWINGS

The different and exemplary features described above can be combined with one another according to the invention, insofar as this is technically sensible and suitable. Further features, advantages and embodiments of the invention are shown in the following description of embodiments and with reference to the drawings. The drawings show

FIG. 1 a side view of an exploded view of an embodiment of an apparatus for connecting an electrical component to an insulated component to be electrically insulated therefrom;

FIG. 2 a perspective view of the embodiment according to FIG. 1 from diagonally below; and

FIG. 3 a perspective view of the embodiment according to FIG. 1 from diagonally above.

### DETAILED DESCRIPTION

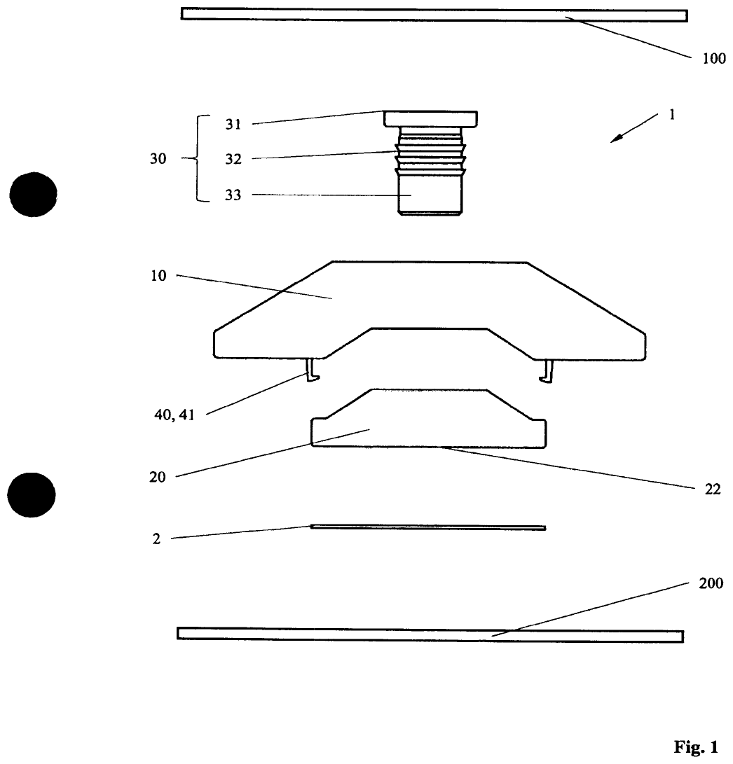

FIG. 1 shows a side view of an exploded view of an embodiment of an apparatus 1 for connecting an electrical component 100 to an insulated component 200 to be electrically insulated therefrom. The electrical component 100 can be, for example, a busbar 100 and/or a circuit board 100. The insulated component 200 to be electrically insulated from the electrical component 100 can be, for example, a housing 200 to which the electrical component 100 is to be attached.

The apparatus 1 comprises an electrically insulating support 10, an electrically insulating heat transfer unit 20 and an attachment unit 30. In addition, the apparatus 1 comprises an optional thermally conductive sheet 2.

The attachment unit 30 is configured to be directly connected to the electrical component 100. In the embodiment example shown in FIG. 1, the attachment unit 30 has a coupling element 31, in particular a coupling surface 31. The attachment unit 30 can be materially connected to the electrical component 100 via the coupling surface 31. For example, the attachment unit 30 can be bonded, welded or screwed to the electrical component 100 via the coupling surface 31. In alternative embodiments, the coupling element 31 can be connected to the electrical component 100 in a force-fitting and/or form-fitting manner.

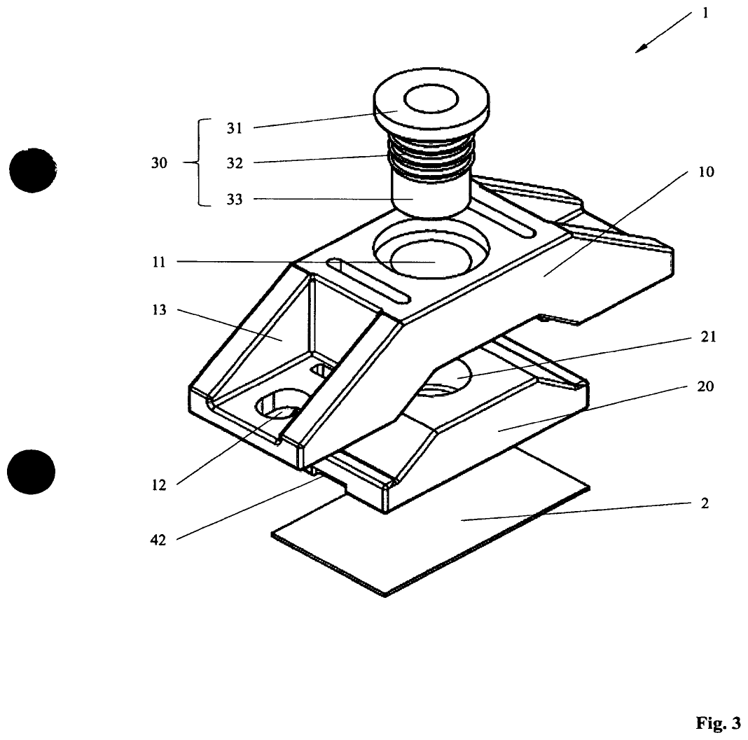

The support 10 is configured to transmit mechanical loads between the electrical component 100 and the insulated component 200. The support 10 is attached to the electrical component 100 by means of the attachment unit 30. In the embodiment example shown in FIG. 1, the attachment unit 30 is connected to the support 10 in a force-fitting and/or form-fitting manner. For this purpose, the attachment unit 30 has a connecting element 32, in particular a threaded surface 32. The threaded surface 32 engages in a corresponding threaded surface of the support 10 when the attachment unit 30 is connected to the support 10. The corresponding threaded surface of the support 10 is arranged in a passage 11 shown in FIG. 3. In alternative embodiments, the connecting element 32 may be configured such that the support 10 can be connected to the attachment unit 30 in a form-fitting manner. For example, the support 10 and the attachment unit 30 could be connected to each other in a form-fitting manner by means of latching lugs.

In the assembled state of the apparatus 1, the attachment unit 30 protrudes through the support 10 in such a way that a heat transfer element 33, in particular a heat conducting surface 33, of the attachment unit 30 contacts the heat transfer unit 20. An optional heat-conducting paste can be inserted between the heat transfer element 33 and the heat transfer unit 20 to improve heat transfer.

The heat transfer unit 20 is configured to transfer thermal loads between the electrical component 100 and the insulated component 200 to be electrically insulated therefrom. Preferably, the heat transfer unit 20 has a greater thermal conductivity, in particular a significantly greater thermal conductivity, than the support 10. The heat transfer unit 20 has a first heat transfer surface 21 not visible in FIG. 1 and a second heat transfer surface 22.

The first heat transfer surface 21 is configured to be connected to the attachment unit 30, in particular the heat transfer element 33 of the attachment unit 30, in a heat-communicating manner in order to introduce heat from the attachment unit 30 into the heat transfer unit 20. The second heat transfer surface 22 is configured to be connected in a heat-communicating manner to the insulated component 200 to be electrically insulated. As shown in FIG. 1, a thermally conductive sheet 2 can be provided between the second heat transfer surface 22 and the insulated component 200. The heat transfer unit 20 can transfer heat to the insulated component 200 via the second heat transfer surface 22. Preferably, the second heat transfer surface 22 is larger than the first heat transfer surface 21.

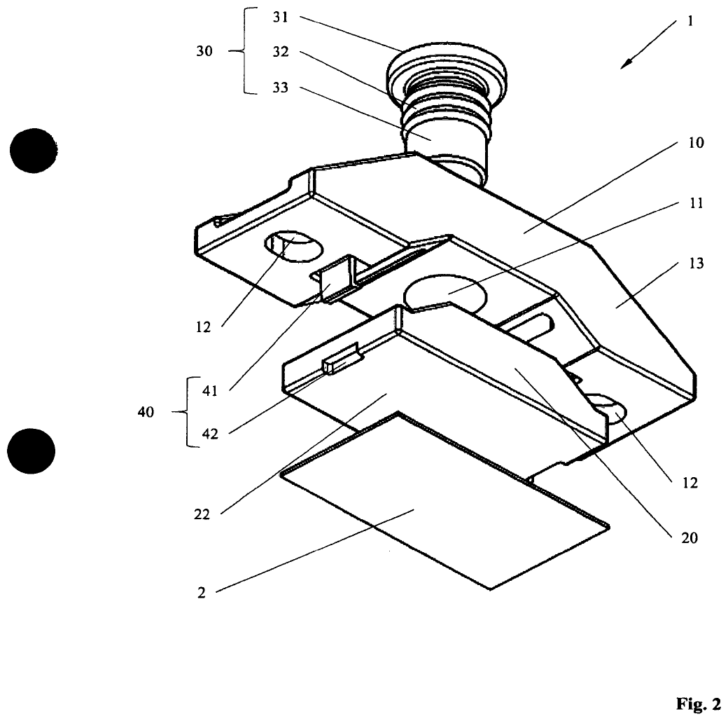

The heat transfer unit 20 can be detachably connected to the support 10 via a snap-fit connector 40. The snap-fit connector 40 comprises two mating parts 41 arranged on the support 10. The mating parts 41 engage in two corresponding snap-in grooves 42 on the heat transfer unit 20 when the heat transfer unit 20 is connected to the support 10. One of the two symmetrically configured snap-in grooves 42 is shown in FIG. 2.

FIG. 2 shows the embodiment of the apparatus 1 of FIG. 1 in a perspective view from below. The electrical component 100 and the insulated component 200 to be electrically insulated therefrom are not shown in FIG. 2 for reasons of clarity.

When the heat transfer unit 20 and the support 10 are connected to each other, the mating parts 41 bend elastically outwards. The snap-in grooves 42 are arranged on the heat transfer unit 20 in such a way that, when the support 10 and the heat transfer unit 20 are in the desired position relative to each other, the mating parts 41 can snap into the snap-in grooves 42. When they snap into place, the mating parts 41 move back into their original position and hook into the snap-in grooves 42. If the heat transfer unit 20 is to be released from the support 10 again, for example if the heat transfer unit 20 is to be replaced by a heat transfer unit 20 with a different thermal conductivity, the mating parts 41 can be released from their engagement with the snap-in grooves 42. For this purpose, the mating parts 41 can be bent elastically outwards again.

As shown in FIG. 2 and FIG. 3, the support 10 comprises a passage 11. When the apparatus 1 connects the electrical component 100 to the insulated component 200, the attachment unit 30 extends through the passage 11. Preferably, the threaded surface 32 of the attachment unit 30 engages in a corresponding threaded surface, not shown, in the passage 11 in order to connect the attachment unit 30 immovably to the support 10. Alternatively, knurling or undercuts would also be possible instead of a thread, so that the attachment unit 30 can be pressed into the support 10.

Such an arrangement ensures that mechanical loads are transmitted from the electrical component 100 to the support 10 via the attachment unit 30. The support 10 transmits these mechanical loads to the insulated component 200 to be electrically insulated from the electrical component 100. Alternatively, the mechanical loads can be transmitted in the opposite direction via the same arrangement.

FIG. 3 shows the embodiment of the apparatus 1 of FIG. 1 in a perspective view from diagonally above. The electrical component 100 and the insulated component 200 are not shown in FIG. 3 for reasons of clarity.

As indicated in FIG. 3, the heat transfer element 33 of the attachment unit 30 protrudes through the support 10. Preferably, the heat transfer element 33 of the attachment unit 30 is in planar contact with the first heat transfer surface 21 of the heat transfer unit 20 when the apparatus 1 connects the electrical component 100 to the insulated component 200.

Such an arrangement ensures that thermal loads are transferred from the electrical component 100 to the heat transfer unit 20 via the attachment unit 30. The heat transfer unit 20 transmits the thermal loads, in particular the waste heat of the electrical component 100, to the insulated component 200 to be electrically insulated from the electrical component 100.

The support 10 has two holes 12. The holes 12 are arranged symmetrically on the support 10 and are configured as long holes 12. In order to be able to fasten the support 10 to the insulated component 200, fastening elements such as screws and/or rivets or bolts can be passed through the holes 12 and fixed to the insulated component 200.

In the embodiment example of the apparatus 1 shown in FIGS. 1-3, the support 10 is designed as a lightweight component. For this purpose, the support 10 comprises a support structure 13. Due to the support structure 13, the support 10 has the necessary rigidity to transmit the mechanical loads, in particular forces and/or torques, between the electrical component 100 and the insulated component 200 to be electrically insulated therefrom. Support structure 13 is a stiffening structure.

### LIST OF REFERENCE SIGNS

1 apparatus
2 thermally conductive sheet
10 support
11 passage
12 hole
13 support structure
20 heat transfer unit
21 first heat transfer surface
22 second heat transfer surface
30 attachment unit
31 coupling element
32 connecting element
33 heat transfer element
40 snap-fit connector
41 mating part and
42 snap-in groove
100 electrical component/busbar
200 (electrically) insulated component/housing

1. An apparatus for connecting an electrical component to an insulated component electrically insulated therefrom, the apparatus comprising:
an electrically insulating support for transmitting mechanical loads between the electrical component and the insulated component electrically insulated therefrom;
an electrically insulating heat transfer unit for transmitting thermal loads between the electrical component and the insulated component electrically insulated therefrom; and
an attachment unit directly connectable to the electrical component for attaching the support to the electrical component,
wherein the heat transfer unit being is releasably connected to the support.

2. The apparatus according to claim 1, wherein the attachment unit is configured to transmit mechanical loads between the electrical component and the support, as well as thermal loads between the electrical component and the heat transfer unit.

3. The apparatus according to claim 1, wherein the support is configured to be connected to the insulated component in a form-fitting and/or force-fitting manner.

4. The apparatus according to claim 1, wherein the support and the heat transfer unit are connected to one another in a form-fitting manner.

5. The apparatus according to claim 1, wherein the support and the heat transfer unit are made from an electrically insulating plastic.

6. The apparatus according to claim 1, wherein the support and/or the heat transfer unit are/is manufactured by injection moulding.

7. The apparatus according to claim 1, wherein the support is configured to be thermally insulating or has a lower thermal conductivity than a thermal conductivity of the heat transfer unit.

8. The apparatus according to claim 1, wherein the heat transfer unit has a thermal conductivity of more than 1.5 W/(m·K).

9. The apparatus according to claim 1, wherein the heat transfer unit comprises a first heat transfer surface configured to be connected to the electrical component in a heat-communicating manner, and a second heat transfer surface, configured to be connected to the insulated component electrically insulated from the electrical component in a heat-communicating manner, wherein the first heat transfer surface is smaller than the second heat transfer surface.

10. A connection assembly comprising:
a) a busbar;
b) a housing; and
c) an apparatus according to claim 1, wherein the busbar and the housing are connected to each other by the apparatus.

11. The connection assembly according to claim 10, wherein the busbar and the housing are detachably connected to each other.

12. The apparatus according to claim 4, further comprising a releasable snap fit connector connecting the support and the heat transfer unit in a form-fitting manner.
